(19) United States
(12) Patent Application Publication
(10) Pub. No.: US 2004/0136163 A1
(43) Pub. Date: Jul. 15, 2004

(54) Heat sink device having light-emitting components

(75) Inventors: Alex Horng, Kaohsiung (TW); Wei-Jen Chen, Kaohsiung (TW)

Correspondence Address: BACON & THOMAS, PLLC, 625 SLATERS LANE, FOURTH FLOOR, ALEXANDRIA, VA, 22314

(73) Assignee: SUNONWEALTH ELECTRIC MACHINE INDUSTRY CO., LTD., Kaohsiung (TW)

(21) Appl. No.: 10/341,476

(22) Filed: Jan. 14, 2003

(51) Int. Cl. H05K 7/20

(52) U.S. Cl. 361/719; 359/538; 361/697

(57) ABSTRACT

A heat sink device having light-emitting components comprises a heat sink, a fan and a plurality of light-emitting components. The heat sink is made of heat conductive material. The fan is received in a recession of the heat sink. The light-emitting components are symmetrically arranged in equi-spaced manner around the recession of the heat sink. Thus, when the fan is rotated, the light-emitting components can emit light performing various colors, flash frequency, reflection and refraction.

### BACKGROUND OF THE INVENTION

1. Field of the Invention

The invention is related to a heat sink device, and more particularly, to a heat sink device having light-emitting components for performing various colors, flash frequency, reflection and refraction when the fan is rotated.

2. Description of the Prior Art

A conventional heat sink device is made of heat conductive material. A plurality of fins is configured on the top surface of the heat sink, and optionally a fan is configured thereon. Therefore, the heat sink device dissipates heat from CPU, chips and other electronic components. Even though the heat sink device can be functioned to dissipate heat, the structural design, however, is apparently limited. Accordingly, it can be seen that product has no additional vision effect for extra promotion.

A conventional fan blade structure is installed around a headlight of a bicycle. A plurality of light-emitting components is arranged in equi-space around the outer periphery of the hollow boss of the fan blade. A generator is installed between the hollow boss and the shaft of the fan. When running airflow drives the fan rotating, the generator supplies power to switching on the light-emitting components so as to enhance the vision effect of the bicycle. However, because the light-emitting components rotate along with the fan, the simultaneous twinkle beam emitted from light-emitting components is monotonous and without any spectacular reflection or refraction. Therefore the vision effects performed by the light-emitting components are still limited. Furthermore, because the light-emitting components rotate along with the fan, there exist potential damages due to rotation and vibration.

The present invention is to modify the drawbacks mentioned above. In the present invention, a plurality of light-emitting components is arranged symmetrical on the heat sink. The light-emitting components emit light performing various color and flash frequency so as to enhance vision effect. While a fan is installed on the heat sink and rotated, light from the light-emitting components performs reflection and refraction. Therefore, the present invention indeed enhances vision effect and increases additional value.

### SUMMARY OF THE INVENTION

The main object of the present invention is to provide a heat sink device having light-emitting components, wherein a plurality of light-emitting components are disposed on the heat sink to perform various effects including flash frequency and color variation, reflection and refraction so as to enhance vision effect and increase additional value.

The heat sink device having light-emitting components in the present invention mainly comprises a heat sink, a fan and a plurality of light-emitting components. The heat sink is made of heat conductive material. The fan is received in a recession of the heat sink. The light-emitting components are symmetrically arranged in equi-spaced manner around the recession of the heat sink. Thus, when the fan is rotated, the light-emitting components can emit light performing various colors, flash frequency, reflection and refraction.

### BRIEF DESCRIPTION OF THE DRAWINGS

FIG. 1 is the exploded perspective view of the first embodiment of the invention.

FIG. 2 is the top view of the first embodiment of the invention.

FIG. 3 is the cross sectional view of FIG. 2.

FIG. 4 is the exploded perspective view of the second embodiment of the invention.

FIG. 5 is the top view of the second embodiment of the invention.

FIG. 6 is the cross sectional view of FIG. 5.

FIG. 7 is the exploded perspective view of the third embodiment of the invention.

### DETAILED DESCRIPTION OF THE INVENTION

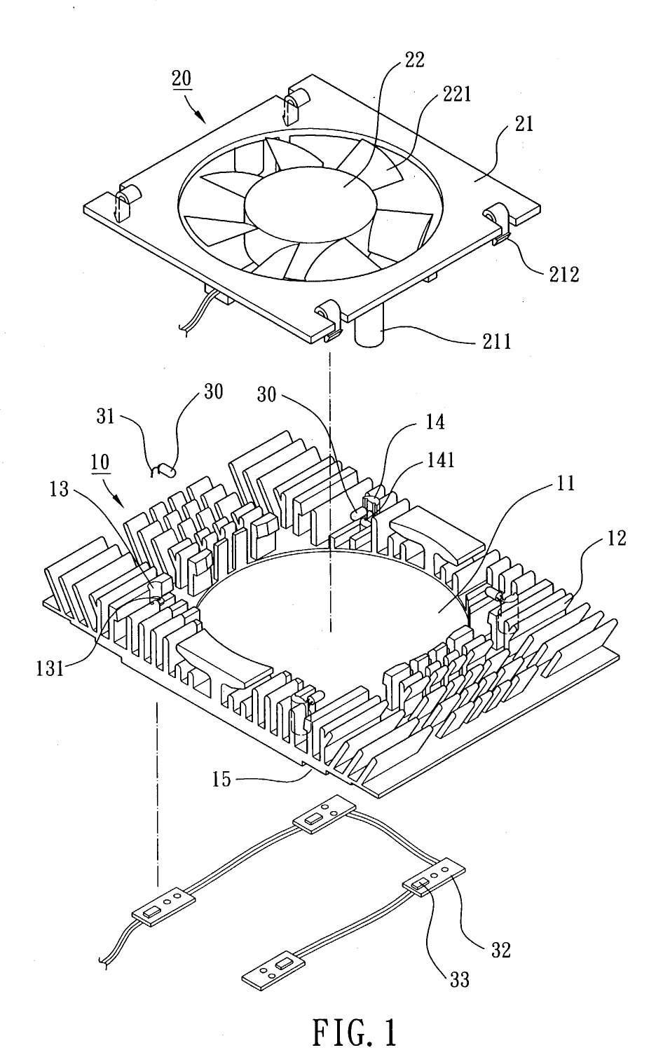

Referring to FIGS. 1 to 3, the heat sink device having light-emitting components in the present invention mainly comprises a heat sink 10, a fan 20 and a plurality of light-emitting components 30. The heat sink 10 is made of heat conductive material. The fan 20 is received in a recession 11 of the heat sink 10. The light-emitting components 30 are symmetrically arranged in equi-spaced manner around the recession 11 of the heat sink 10. When the fan 20 is rotated, the light-emitting components 30 can emit light performing various colors, flash frequency, reflection and refraction.

Referring again to FIGS. 1 to 3, the detailed structure of the heat sink 10 and the fan 20 in the present invention is disclosed. The heat sink 10 is made of heat conductive material such as aluminum, copper etc. and provided with a plurality of fins 12 and a recession 11, adapted to receive the fan 20 therein, on the front side of the heat sink 10. The fins 12 are extended in vertical or inclined upward from the front surface of the heat sink 10 to form a projected portion shaped Y type, T type or inverted L type. In addition to increasing heat dissipation area, and parts of the fins 12 are preferably formed with socket caves 13 or socket posts 14 to receive or hold light-emitting components 30. The socket caves 13 and the socket posts 14 are symmetrically arranged in equi-spaced manner around the recession 11 and particularly at the corners of the recession 11. The fan 20 is a suspensory fan or an inverted type fanand generally comprises a frame 21 and a rotor 22. The frame 21 selectively utilizes a plurality of posts 211 and/or a plurality of hooks 212 to be secured on the heat sink 10 by screwing or hooking. Meanwhile, the rotor 22 comprises a plurality of blades 221 adapted to allow airflow passing therebetween and thereby increase heat dissipation efficiency.

Referring again to FIGS. 1 to 3, the light-emitting components 30 are preferably light-emitting diodes (LED) with different colors such as red, yellow, green, blue or white light. The light-emitting components 30 are mainly received in the associated socket cave 13 or held at the associated socket post 14 on the heat sink 10. Thus the light-emitting components 30 are symmetrically arranged around the recession 11 or at the corners of the recession 11. A plurality of pins 31 of the light-emitting components 30 are extended through the holes 131, 141 formed on the socket cave 13 and socket post 14, thereby electrically connecting to at least one circuit board 32. Furthermore, each of the circuit boards 32 are serially connected by wires and is secured on corresponding positions on the back of the heat sink 10 aligned with the recessions by selectively screwing, adhering, or hooking. The circuit board 32 may optionally have a plurality of electronic components 33 such as resistor, ASIC etc. to provide the light-emitting components 30 used for flash frequency modulation and voltage stabilization.

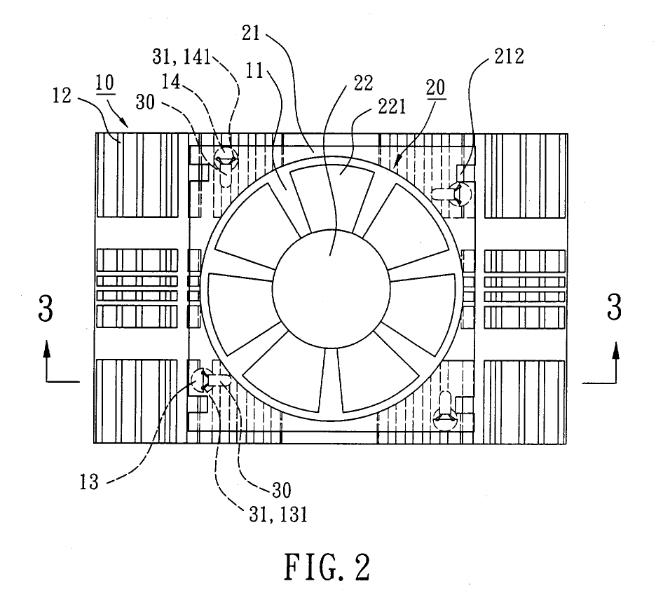

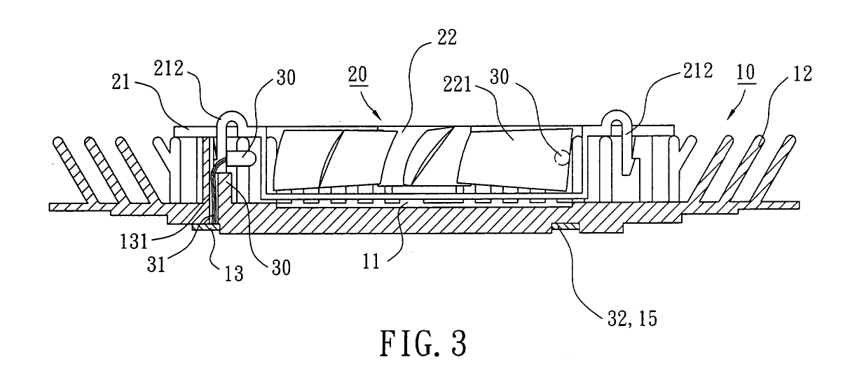

Referring again to FIGS. 2 to 3, the heat sink 10 is mainly used in a desktop computer or a notebook computer to dissipate heat generated from CPU or ICs mounted on an interface card. The heat sink 10 having light-emitting components 30 is particularly used in a transparent casing of a desktop computer or a notebook computer to provide various vision effects for increasing additional value, in addition to heat-dissipation function. Furthermore, the light-emitting components 30 can be chosen in various positions to emit light with different flash frequency and color on the fins l2 and upstream section or downstream section of the blades 221. When the light is emitted on the upstream or downstream section of the blades 221, the rotation of the blade 221 causes the reflection effect of the light. In particular, if the rotor 22 and the blade 221 are made of transparent material, the rotation of the blade 221 can cause more brilliant refraction effect.

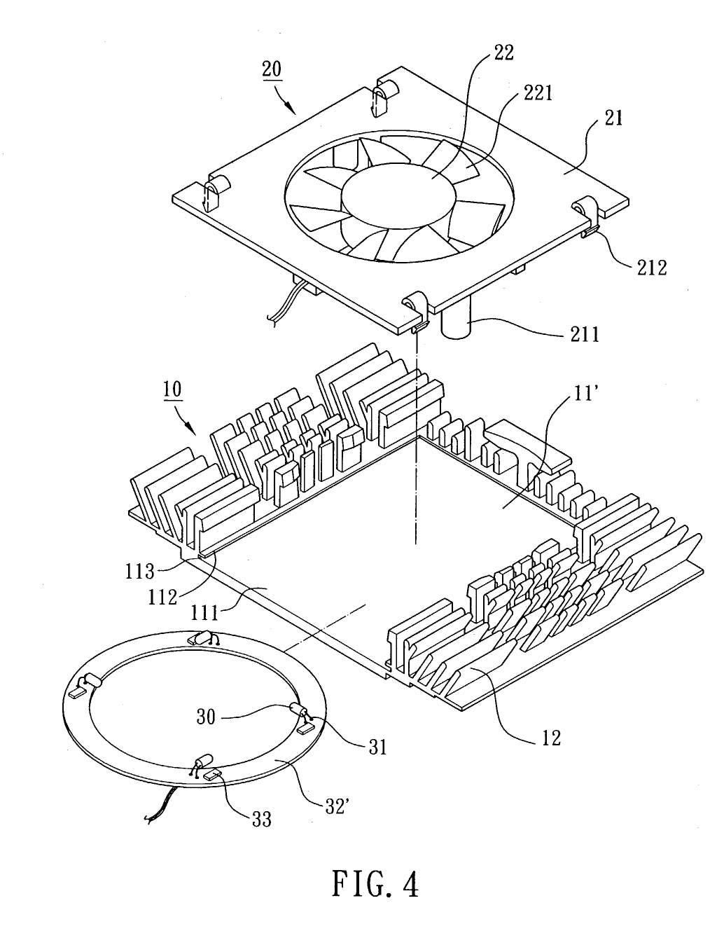

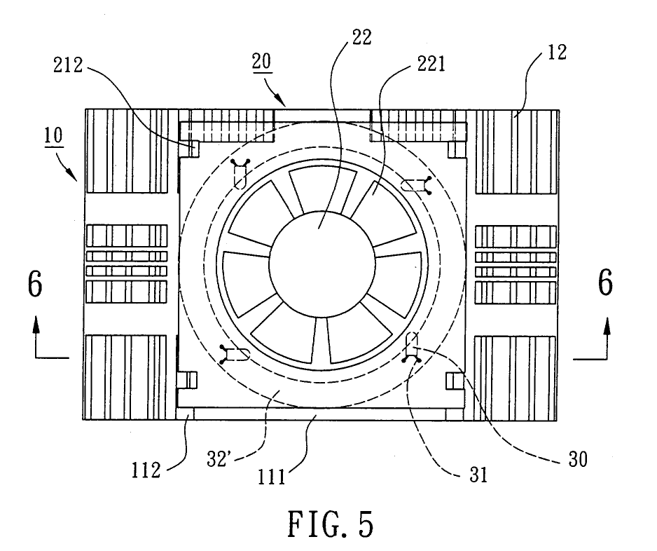

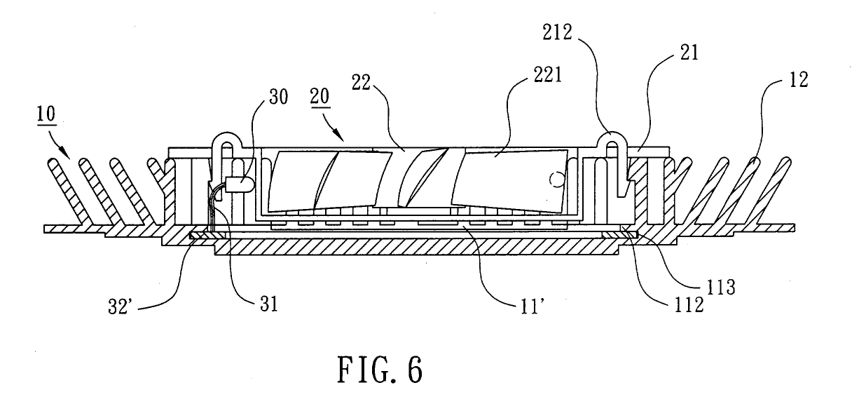

Referring to FIGS. 4 to 6, a second preferred embodiment of the present invention is disclosed. The heat sink 10 is provided with an opening 111 on one side of the recession 11′ for easily installing the light-emitting components 30. A flange 112 is disposed on two opposite sides of the recession 11′ so as to form a groove 113 on the recession 11′. Meanwhile, the light-emitting components 30 are directly installed on the annular circuit board 32′. In assembling operation, the opening 111 allows passage of the circuit board 32′ and engaging relationship of a rim of the annular circuit board 32′ with the groove 113 so that the annular circuit board 32′ is conveniently fixed in the recession 11′. Furthermore, number, type or arrangement of the light-emitting components 30 on the circuit board 32′ in the second embodiment can be varied depending on demand and requirement on condition that heat dissipation efficiency of the heat sink 10 and the fin 20 is allowed or maintained. Then an installing space thereof can also be increased.

The configuration of the recession 11′ can be designed as a square, a rectangular or U-shape. The configuration of circuit board 32′ may also be varied corresponding to the recession 11′ such as an annular shape. Additionally, Utilizing screws adhesives or hooks may reinforce an assembled relationship of the circuit board 32′ mentioned above.

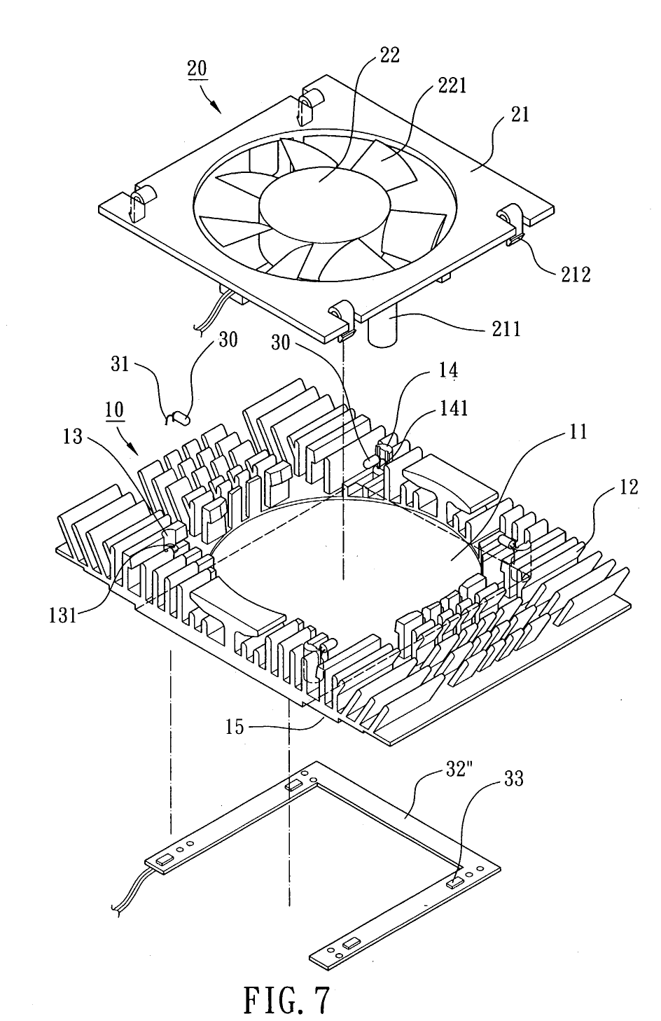

Referring to FIG. 7, a third preferred embodiment of the present invention is disclosed. Comparing with the first and the second preferred embodiments, the circuit board 32″ is formed as an inverted U shape. Being arranged in the recession 15 on the back of the heat sink 10 same as the first and the second preferred embodiments, the circuit board 32″ can accomplish reducing its dimensions, which remains a widen space for installing its electronic components 33 and welding the light-emitting components 30 convenient. Therefore, time for assembling operation is shortened and variations of the products are multiplied.

Referring again to FIG. 1, the present invention is a heat dissipation device provided with a plurality of light-emitting components 30 arranged symmetrically on the heat sink 10 to perform various flash frequencies and colors that enhances vision effect of the heat sink 10. For more various reflections and refraction of light, it can be designed that the heat sink 10 incorporates with rotation of the fan 20. In contrast with the conventional heat sink, the present invention enhances vision effect and increase additional value of products.

While the present invention has been described with reference to the preferred embodiments thereof, it is to be understood that the invention is not limited to the described embodiments or constructions. On the contrary, the invention is intended to cover various modifications and similar arrangements as would be apparent to those skilled in the art. Therefore, the scope of the appended claims should be accorded the broadest interpretation so as to encompass all such modifications and similar arrangements.

What is claimed is

1. a heat sink device comprising:
a heat sink made of heat conductive material and provided with a plurality of fins;
at least one light-emitting component configured on the said heat sink and performing various lighting effect to enhance vision effect of the heat sink; and
at least one circuit board assembled to the heat sink to electrically connect to the light-emitting component.

2. The heat sink device as claimed in claim 1, wherein the light-emitting component is a light-emitting diode.

3. The heat sink device as claimed in claim 1, wherein a recession is formed on the heat sink, and the light-emitting components are arranged symmetrically around the recession.

4. The heat sink device as claimed in claim 3, wherein the light-emitting component is installed at corners of the recession.

5. The heat sink device as claimed in claim 1, further comprising a fan fixed on the heat sink, and provided with a rotor and a plurality of blades thereof; when the rotor is rotated, the light-emitting components emit light on the blades to perform reflection effect.

6. The heat sink device as claimed in claim 5, wherein the fan further includes a frame provided with a plurality of posts and hooks to thereby secure the fan on the heat sink.

7. The heat sink device as claimed in claim 5, wherein light of the light-emitting component is emitted on upstream and downstream sections of the blades.

8. The heat sink device as claimed in claim 1, wherein light of the light-emitting components is emitted on the fins of the heat sink.

9. The heat sink device as claimed in claim 1, wherein the heat sink is used in a computer provided with a transparent casing.

10. The heat sink device as claimed in claim 5, wherein the blades are made of transparent material so that when the fan is rotated, the light-emitting components emit light on the blades of the fan to perform refraction effect.

11. The heat sink device as claimed in claim 1, wherein the fins of the heat sink is formed with socket caves adapted to receive the light-emitting component.

12. The heat sink device as claimed in claim 1, wherein the fins of the heat sink is formed with socket posts adapted to hold the light-emitting component.

13. The heat sink device as claimed in claim 11, wherein the socket caves are provided with a plurality of holes so that pins of the light-emitting component extend through the holes to electrically connect to the circuit board.

14. The heat sink device as claimed in claim 12, wherein the socket posts are provided with a plurality of holes so that pins of the light-emitting component extend through the holes to electrically connect to the circuit board.

15. The heat sink device as claimed in claim 1, further comprising a plurality of electronic components configured on the circuit board adapted to control the light-emitting components.

16. The heat sink device as claimed in claim 1, wherein the circuit board is serially connected to circuit boards by wires.

17. The heat sink device as claimed in claim 1, wherein the circuit board is formed with an inverted U shape.

18. The heat sink device as claimed in claim 1, wherein there is a recession formed on a back of the heat sink for receiving and securing the circuit board.

19. The heat sink device as claimed in claim 3, wherein a opening is formed at one side of the recession of the heat sink, and a flanges is extended along two opposite sides of the recession to form grooves for securing the circuit board.

20. The heat sink device as claimed in claim 19, wherein the circuit board is formed as an annular shape and the light-emitting component is installed on the annular circuit board.
